(19) United States
(12) Patent Application Publication
(10) Pub. No.: US 2025/0351259 A1
(43) Pub. Date: Nov. 13, 2025

(54) HEAT SINK ASSEMBLY WITH SPRING-ADJUSTABLE HEAT PIPE FOR IMPROVED HEAT DISSIPATION, AND RELATED CIRCUIT BOARD ASSEMBLIES AND ASSEMBLY METHODS

(71) Applicant: QUALCOMM Incorporated, San Diego, CA (US)

(72) Inventors: Shankar Gopalakrishna, Bengaluru (IN); Dhinesh Jambai Gopu, Bengaluru (IN); Abhith M, Bengaluru (IN)

(21) Appl. No.: 18/659,325

(22) Filed: May 9, 2024

(51) Int. Cl. H05K 1/02; H05K 7/20

(52) U.S. Cl. CPC H05K 1/0204; H05K 7/20409; H05K 7/2049; H05K 2201/06

(57) ABSTRACT

Heat sink assembly with spring-adjustable heat pipe for improved heat dissipation, and related circuit board assemblies and methods of assembling. The heat sink assembly can be thermally coupled to an electronic device, such as a printed circuit board (PCB) and/or an IC chip(s) mounted on a circuit board to dissipate heat generated from electronic devices. The heat sink assembly includes a heat sink with a spring-adjustable heat pipe between a first electronic device and a heat sink to fill in gap space therebetween and to thermally couple the heat sink to the first electronic device. The spring effect of the spring-adjustable heat pipe provides upward resilient force towards the heat sink when the heat sink is in contact with and applies a downward force onto the spring-adjustable heat pipe to provide a compressed, tight coupling between the heat sink and the spring-adjustable heat pipe for enhanced good thermal coupling.

### TECHNICAL FIELD

The field of the disclosure relates to heat sinks that include cooling fins that can be thermally coupled to integrated circuit (IC) chips to dissipate heat.

### BACKGROUND

Integrated circuits (ICs) are the cornerstone of electronic devices. ICs are packaged in an IC package, also called a “semiconductor chip” or “IC chip.” An electronic device can include one or more IC chips mounted on and electrically coupled to a substrate, such as a printed circuit board (PCB), to provide physical support and an electrical interface to the IC chip(s). For example, one type of IC chip that is typically a higher power consuming device is a system-on-a-chip (SoC) that includes a processor and other supporting circuity within a single IC chip. Other types of IC chips also include high-power consuming circuitry. Heat is generated by IC chips as a result of energy losses from the powered operation of the circuits. As the circuitry in the IC chip becomes more powerful in terms of increases in functionality and operational speeds as well as becoming more compact in size, the IC chip generates an increasing amount of heat due to the high-speed electron flow. Excessive heat can increase the junction temperature of the IC chip and degrade its performance and reliability, and in extreme cases causes the circuitry in the IC chip to fail due to exceeding its thermal limit. An IC chip may also have a temperature limitation for operation based on its circuit performance criteria (e.g., a circuit will have a thermal limit at which performance starts to decrease), to extend battery life, and/or to maintain temperature within “skin limits.”

Thus, it is important to provide techniques to maintain the junction temperature of an IC chip within desired limits based on its heat generation. One method to maintain an IC chip within a desired junction temperature is to provide a heat sink that is thermally coupled to the IC chip to dissipate heat. For example, the heat sink can be provided as a metal block that includes metal cooling fins that have an increased thermal conductivity over ambient air to enhance heat dissipation. The heat sink dissipates heat by conducting heat away from a heat source, such as an IC chip, and spreading it throughout the heat sink. The heat is then transferred from a solid surface to a fluid or gas through the surrounding air through convection. The air that comes in contact with the hot surfaces of the heat sink becomes warmer, less dense, and rises, such that cooler surrounding air replaces the rising arm air and creates a continuous flow of air over the heat sink. This convective air flow carries heat away from the heat sink and into the surrounding environment for heat dissipation. A fan can also be employed to increase air flow across the heat sink and increase the heat dissipation rate to maintain the temperature of the IC chip within desired temperature limits.

Even when a heat sink is employed to dissipate heat from an IC chip, heat dissipation is becoming more challenging, especially for hand-held or mobile devices where mechanical space to provide a heat sink and heat dissipation is limited. It is therefore desirable to provide more efficient ways to dissipate heat in an IC package and IC chip environment.

### SUMMARY

Aspects disclosed in the detailed description include a heat sink assembly with a spring-adjustable heat pipe for improved heat dissipation. Related circuit board assemblies and methods of assembling such heat sink assemblies are also disclosed. The heat sink assembly can be thermally coupled to an electronic device, such as a printed circuit board (PCB) and/or an IC chip(s) mounted on a circuit board that extends in first, horizontal directions, to dissipate heat generated from electronic device. In exemplary aspects, the heat sink assembly includes a heat sink configured to be thermally coupled to a first electronic device (e.g., an IC chip) mounted on a circuit board in a second, vertical direction. The heat sink is thermally coupled to the first electronic device to dissipate heat generated by the first electronic device. It may also be desired to provide for the heat sink to be a single heat sink that is also coupled to a second electronic device(s) on the circuit board to achieve a benefit of increased heat dissipation from a larger heat sink. However, the second electronic device(s) may have a larger height off of the circuit board in the second, vertical direction than the first electronic device, thus creating a gap space between the heat sink and the first electronic device in the second, vertical direction.

In this regard, in exemplary aspects, the heat sink assembly includes a spring-adjustable heat pipe that is a heat pipe shaped to form a spring (e.g., a bent cantilevered spring). A heat pipe is a metal pipe that includes an internal chamber with liquid configured to absorb heat causing the liquid to evaporate into vapor, which is then released for efficient heat transfer to the heat sink before condensing back into a liquid. The spring-adjustable heat pipe is disposed between the first electronic device and the heat sink in the second, vertical direction to fill in the gap space between the first electronic device and the heat sink and to thermally couple the heat sink to the first electronic device. The spring effect of the spring-adjustable heat pipe is configured to provide an upward resilient force in the second, vertical direction towards the heat sink when the heat sink is in contact with and applies a downward force in the second, vertical direction onto the spring-adjustable heat pipe. Fasteners, such as spring-loaded screws, can be coupled to the heat sink to cause the heat sink to apply a downward force onto the spring-adjustable heat pipe in the second, vertical direction to provide a compressed, tight coupling between the heat sink and the spring-adjustable heat pipe to provide a good thermal coupling between the heat sink and the first electronic device. In this manner, a thicker thermal interface (e.g., a thermal paste) does not have to be used to bridge the gap space between the first electronic device and the heat sink, which may provide a reduced performance thermal interface to the first electronic device. Also, the heat pipe being a spring-adjustable heat pipe can reduce the need to provide a thermally conducive component (as an alternative to a thicker thermal paste) between the heat sink and the coupled electronic device that needs to be manufactured within a very precise tolerance, because the spring-adjustable heat pipe can be flexibly compressed in the second, vertical direction to be tightly coupled to the first electronic device within a larger tolerance range of gap space distances between the heat sink and the pedestal.

In other exemplary aspects, the heat sink assembly includes a thermally conductive pedestal that supports the spring-adjustable heat pipe and the thermal coupling of the spring-adjustable heat pipe to the first electronic device. The pedestal is configured to be disposed in contact with the first electronic device to provide a thermal interface to the first electronic device. An optional thermal paste may be disposed between the pedestal and the first electronic device to enhance the thermal coupling between the pedestal and the first electronic device. The spring-adjustable heat pipe is disposed on and is in thermal contact with the pedestal. For example, the pedestal may include one or more slots that are configured to receive one or more respective elongated metal sections of the spring-adjustable heat pipe to secure the heat pipe in physical contact with the pedestal. These respective elongated metal sections of the spring-adjustable heat pipe can be bent in the second, vertical direction back onto themselves and disposed above the pedestal (e.g., in a C-shape) to provide an integrated spring in the spring-adjustable heat pipe.

In yet other exemplary aspects, the heat sink is configured to receive spring-loaded fasteners that are fasteners with springs loaded onto their shaft. The spring-loaded fasteners are configured to be fastened to the circuit board and controllably fastened to control the compression of their springs against the heat sink to cause the heat sink to apply a downward force towards the circuit board and the first electronic device in the second, vertical direction. The downward force of the heat sink is applied to the spring-adjustable heat pipe to provide a compressive and tight coupling to the spring-adjustable heat pipe for a good thermal coupling. The amount of downward force applied by the heat sink can be varied according to the amount of tightening of the fasteners that control the amount of compression of its springs.

In another example, the heat sink can be configured to receive two different types of spring-loaded fasteners. In this regard, the heat sink may be configured to receive first spring-loaded fasteners that are configured to be controllably fastened to the circuit board. The first spring-loaded fasteners secure the heat sink to the circuit board and cause the heat sink to apply a first downward force towards the circuit board to thermally couple the heat sink to the electronic devices on the circuit board. The heat sink may also be configured to receive second spring-loaded fasteners that intersect the pedestal of the heat sink assembly in the second, vertical direction and are configured to be secured to the pedestal. In this manner, the second spring-loaded fasteners can be adjusted to more precisely control the second downward force applied by the heat sink onto the spring-adjustable heat pipe in the second, vertical direction. In this manner, as an example, the first spring-loaded fasteners can be controllably fastened to cause the heat sink to be secured to the circuit board and generally thermally coupled to electronic devices on the circuit board at a first pressure. The second spring-loaded fasteners can be separately and precisely controllably fastened to cause the heat sink to apply second downward force directly on the spring-adjustable heat pipe at a second, different second pressure in the second, vertical direction to thermally couple the heat sink to the spring-adjustable heat pipe.

In this regard, in one exemplary aspect, an electronic device including a heat sink assembly is disclosed. The heat sink assembly includes a heat sink extending in a first direction, wherein the heat sink comprising a first side and a second side opposite the first side in a second direction orthogonal to the first direction. The heat sink assembly also includes a pedestal configured to be coupled to a first electronic device. The heat sink assembly also includes a first non-linear heat pipe spring-loaded between the first side of the heat sink and the pedestal.

In another exemplary aspect, a method of assembling a heat sink assembly in an electronic device is disclosed. The method includes providing a circuit board extending in a first direction, coupling a first electronic device to the circuit board. The method also includes coupling a first side of a pedestal to the first electronic device such that the first electronic device is between the circuit board and the pedestal in a second direction orthogonal to the first direction. The method further includes coupling a first non-linear heat pipe to a second side of the pedestal opposite the first side of the pedestal in the second direction. The method also includes coupling a heat sink extending in the first direction to the first non-linear heat pipe to spring load the first non-linear heat pipe between the heat sink and the pedestal.

### BRIEF DESCRIPTION OF THE DRAWINGS

FIGS. 1A and 1B are side and top views, respectively, of an exemplary circuit board assembly that includes electronic devices in the form of integrated circuit (IC) chips of differing heights mounted to the circuit board, with a single heat sink coupled to the IC chips to be thermally coupled to the IC chips for heat dissipation;

FIG. 2A is a perspective side view of an exemplary circuit board assembly that includes first and second electronic devices in the form of IC chips of a respective first height and second height greater than the first height and in the form of integrated circuit (IC) chips mounted to the circuit board, wherein the circuit board assembly also includes a heat sink assembly that includes a spring-adjustable heat pipe secured between and thermally coupled to the first electronic device and a heat sink (shown in hidden lines) to provide an upward resilient force in a vertical direction towards the heat sink in response to the heat sink applying a downward force in the vertical direction onto the spring-adjustable heat pipe, to provide a compressed, tight coupling between the heat sink and the spring-adjustable heat pipe to provide a good thermal coupling between the heat sink and the first electronic device;

FIG. 2B is a perspective side view of the circuit board assembly in FIG. 2A, but with the heat sink also shown;

FIG. 2C is a close-up perspective side view of the circuit board assembly in FIG. 2A;

FIG. 2D-1 is a front side view of the circuit board assembly in FIG. 2A;

FIG. 2D-2 is a close-up, front side view of the circuit board assembly in FIG. 2D-1;

FIG. 2E is a close-up, left side view of the circuit board assembly in FIG. 2A

FIG. 2F is a side perspective exploded view of the circuit board assembly in FIG. 2A;

FIG. 3 is a flowchart illustrating an exemplary assembly process of assembling the circuit board assembly in FIG. 2A, including assembling the heat sink assembly therein;

FIGS. 4A and 4B is a flowchart illustrating another exemplary assembly process of assembling the circuit board assembly in FIG. 2A, including assembling the heat sink assembly therein;

FIGS. 5A-5D are exemplary fabrication stages of the assembly process of assembling the circuit board assembly, including assembling the heat sink assembly therein, as described in FIGS. 4A and 4B;

FIG. 6A is a side view of another exemplary circuit board assembly similar to the circuit board assembly in FIG. 2A, but wherein the heat sink assembly includes another exemplary spring-adjustable heat pipe in the form of a bent spring to provide an upward resilient force in a vertical direction towards the heat sink in response to the heat sink applying a downward force in a vertical direction onto the spring-adjustable heat pipe, to provide a compressed, tight coupling between the heat sink and the spring-adjustable heat pipe to provide a good thermal coupling between the heat sink and a first electronic device;

FIG. 6B is a close-up, bottom perspective exploded view of the circuit board assembly in FIG. 6A;

FIGS. 7A and 7B is a flowchart illustrating another exemplary assembly process of assembling the circuit board assembly in FIG. 6A, including assembling the heat sink assembly therein;

FIGS. 8A-8D are exemplary fabrication stages of the assembly process of assembling the circuit board assembly, including assembling the heat sink assembly therein, as described in FIGS. 7A and 7B;

FIG. 9 is a block diagram of an exemplary processor-based system that can be provided in a circuit board assembly that includes a heat sink assembly that includes a spring-adjustable heat pipe secured between and thermally coupled to the first electronic device and a heat sink to provide an upward resilient force in a vertical direction towards the heat sink in response to the heat sink applying a downward force in a vertical direction onto the spring-adjustable heat pipe, to provide a compressed, tight coupling between the heat sink and the spring-adjustable heat pipe to provide a good thermal coupling between the heat sink and a first electronic device including, but not limited to, the circuit board assemblies with their heat sink assemblies in FIGS. 2A-2F, 5D, 6A-6B, and 8D, and that can be assembled in an assembly process including, but not limited to, the assembly processes in FIGS. 3, 4A-4B, and 7A-7B; and

FIG. 10 is a block diagram of an exemplary wireless communications device that includes radio-frequency (RF) components that can be provided in a circuit board assembly that includes a heat sink assembly that includes a spring-adjustable heat pipe secured between and thermally coupled to a first electronic device and a heat sink to provide an upward resilient force in a vertical direction towards the heat sink in response to the heat sink applying a downward force in a vertical direction onto the spring-adjustable heat pipe, to provide a compressed, tight coupling between the heat sink and the spring-adjustable heat pipe to provide a good thermal coupling between the heat sink and the first electronic device including, but not limited to, the circuit board assemblies with their heat sink assemblies in FIGS. 2A-2F, 5D, 6A-6B, and 8D, and that can be assembled in an assembly process including, but not limited to, the assembly processes in FIGS. 3, 4A-4B, and 7A-7B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include a heat sink assembly with a spring-adjustable heat pipe for improved heat dissipation. Related circuit board assemblies and methods of assembling such heat sink assemblies are also disclosed. The heat sink assembly can be thermally coupled to an electronic device, such as a printed circuit board (PCB) and/or an IC chip(s) mounted on a circuit board that extends in first, horizontal directions, to dissipate heat generated from electronic device. In exemplary aspects, the heat sink assembly includes a heat sink configured to be thermally coupled to a first electronic device (e.g., an IC chip) mounted on a circuit board in a second, vertical direction. The heat sink is thermally coupled to the first electronic device to dissipate heat generated by the first electronic device. It may also be desired to provide for the heat sink to be a single heat sink that is also coupled to a second electronic device(s) on the circuit board to achieve a benefit of increased heat dissipation from a larger heat sink. However, the second electronic device(s) may have a larger height off of the circuit board in the second, vertical direction than the first electronic device, thus creating a gap space between the heat sink and the first electronic device in the second, vertical direction.

In this regard, in exemplary aspects, the heat sink assembly includes a spring-adjustable heat pipe that is a heat pipe shaped to form a spring (e.g., a bent cantilevered spring). A heat pipe is a metal pipe that includes an internal chamber with liquid configured to absorb heat causing the liquid to evaporate into vapor, which is then released for efficient heat transfer to the heat sink before condensing back into a liquid. The spring-adjustable heat pipe is disposed between the first electronic device and the heat sink in the second, vertical direction to fill in the gap space between the first electronic device and the heat sink and to thermally couple the heat sink to the first electronic device. The spring effect of the spring-adjustable heat pipe is configured to provide an upward resilient force in the second, vertical direction towards the heat sink when the heat sink is in contact with and applies a downward force in the second, vertical direction onto the spring-adjustable heat pipe. Fasteners, such as spring-loaded screws, can be coupled to the heat sink to cause the heat sink to apply a downward force onto the spring-adjustable heat pipe in the second, vertical direction to provide a compressed, tight coupling between the heat sink and the spring-adjustable heat pipe to provide a good thermal coupling between the heat sink and the first electronic device. In this manner, a thicker thermal interface (e.g., a thermal paste) does not have to be used to bridge the gap space between the first electronic device and the heat sink, which may provide a reduced performance thermal interface to the first electronic device. Also, the heat pipe being a spring-adjustable heat pipe can reduce the need to provide a thermally conducive component (as an alternative to a thicker thermal paste) between the heat sink and the coupled electronic device that needs to be manufactured within a very precise tolerance, because the spring-adjustable heat pipe can be flexibly compressed in the second, vertical direction to be tightly coupled to the first electronic device within a larger tolerance range of gap space distances between the heat sink and the pedestal.

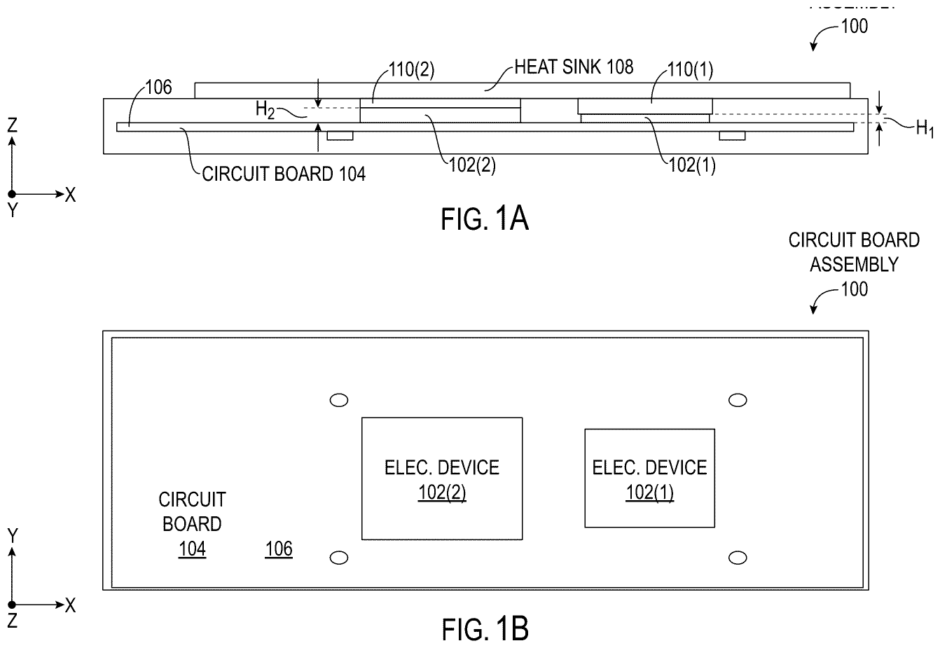

Before discussing examples of circuit board assemblies that include a heat sink assembly including a spring-adjustable heat pipe secured between and thermally coupled to the first electronic device and a heat sink to provide a compressed, tight coupling between the heat sink and the spring-adjustable heat pipe to provide a good thermal coupling between the heat sink and the first electronic device, an exemplary circuit board assembly that does not include a heat sink assembly with a spring-adjustable heat pipe is first discussed with regard to FIGS. 1A and 1B.

FIGS. 1A and 1B are side and top views, respectively, of an exemplary circuit board assembly 100 that includes a first electronic device 102(1) and a second electronic device 102(2) both in the form of integrated circuit (IC) chips. The first and second electronic devices 102(1), 102(2) are both mounted to a circuit board 104 (e.g., a printed circuit board (PCB)) that extends in first, horizontal directions (X-axis and Y-axis directions). FIG. 1A shows the first and second electronic devices 102(1), 102(2) of respective heights H1, H2 in a second, vertical direction (Z-axis direction) from a first, top surface 106 of the circuit board 104. The height H2 of the second electronic device 102(2) is greater than the height H1 of the first electronic device 102(1) in this example, because it is common for different types of electronic devices mounted to a circuit board, such as the circuit board 104, to be of differing heights.

As shown in FIG. 1A, the circuit board assembly 100 also includes a single heat sink 108 that is disposed above and is thermally coupled to the first and second electronic devices 102(1), 102(2) in the second, vertical direction (Z-axis direction) for heat dissipation. A thermal paste 110(1), 110(2) may be provided between the respective first and second electronic devices 102(1), 102(2) and the heat sink 108 to enhance the thermal coupling between the heat sink 108 and the first and second electronic devices 102(1), 102(2). The heat sink 108 is sized large enough to cover the footprint of the first and second electronic devices 102(1), 102(2) in the first, horizontal directions (X-axis and Y-axis directions) to provide a good thermal coupling to the first and second electronic devices 102(1), 102(2) for heat dissipation. The heat sink 108 being a single body (as opposed to providing separate body heat sinks for each of the first and second electronic devices 102(1), 102(2)) has the advantage of not only providing for a larger heat sink for enhanced dissipation through efficient use of space, but it also allows a single larger heat sink 108 to be shared to dissipate heat from both the first and second electronic devices 102(1), 102(2). Thus, if one of the first and second electronic devices 102(1), 102(2) happens to be generating more heat and the other of the first and second electronic devices 102(1), 102(2) is generating less heat, the single heat sink 108 can disproportionately dissipate heat from the first or second electronic device 102(1), 102(2) that is generating more heat for enhanced thermal performance in the circuit board assembly 100.

However, providing a single body heat sink 108 in the circuit board assembly 100 may have a disadvantage with regard to reduced thermal coupling to the first electronic device 102(1). This is because the first electronic device 102(1) has a reduced height H₁, thus increasing the distance in the second, vertical direction (Z-axis direction) orthogonal to the first, horizontal directions (X-axis and Y-axis directions) between the first electronic device 102(1) and the heat sink 108. An increased amount of thermal paste 110(1) can be disposed on the first electronic device 102(1) to provide a contact thermal coupling between the first electronic device 102(1) and the heat sink 108 to “bridge” the larger gap space between the first electronic device 102(1) and the heat sink 108 due to the reduced height H₁ of the first electronic device 102(1). However, an increased amount of thermal paste 110(1) provided on the first electronic device 102(1) reduces thermal transfer efficiency between the first electronic device 102(1) and the heat sink 108. Separate body heat sinks could be employed to avoid the need to provide an increased amount of thermal paste 110(1) to bridge the larger gap space between the first electronic device 102(1) and the heat sink 108. However, this would cause the additional thermal performance benefits of a single body heat sink, like heat sink 108, to be lost. Thus, it may be desired to avoid or reduce the amount of thermal paste used to thermally couple multiple electronic devices of different heights (and especially reduced height devices) in a circuit board assembly, but still use a single body heat sink to dissipate heat for the multiple electronic devices for improved heat dissipation and thermal performance.

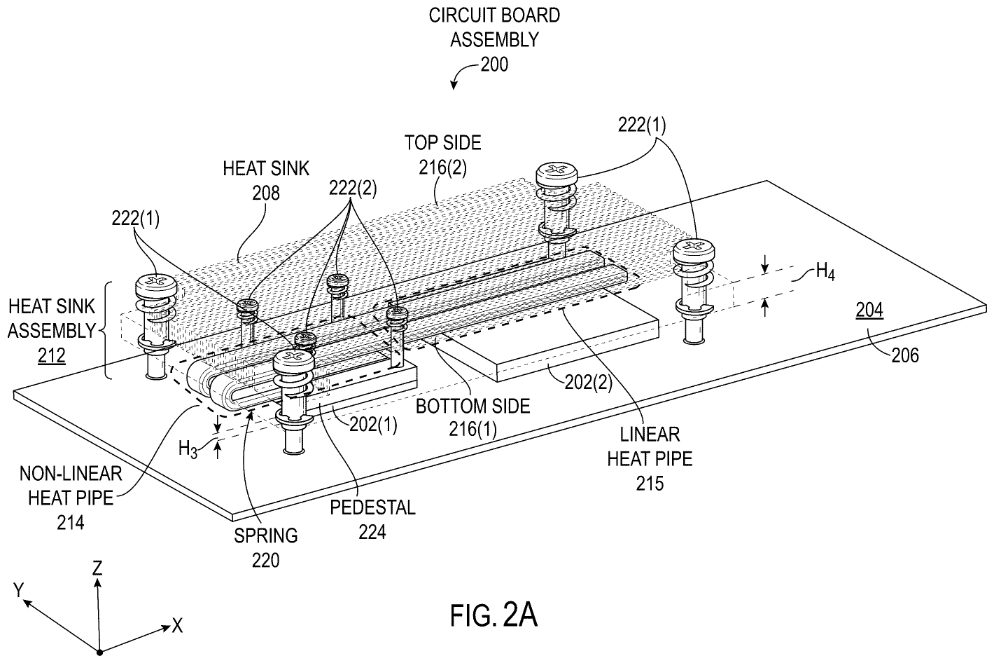

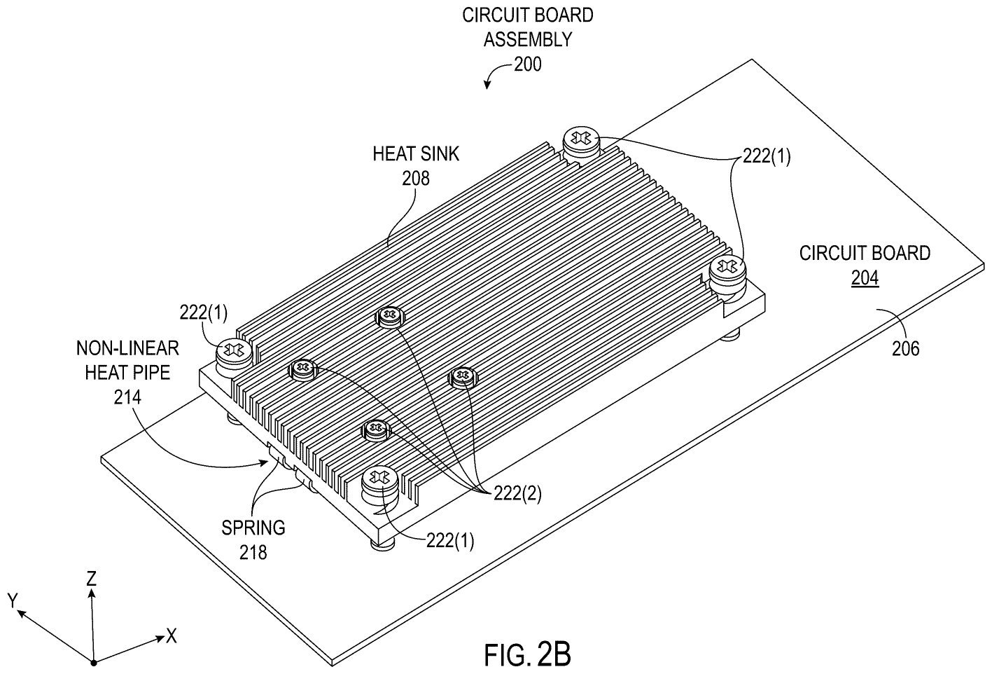

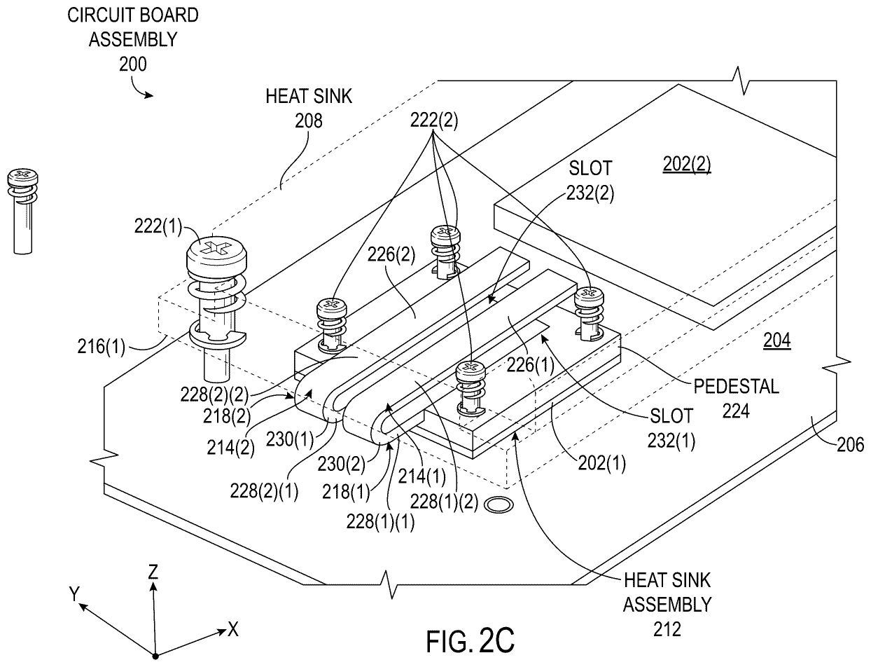

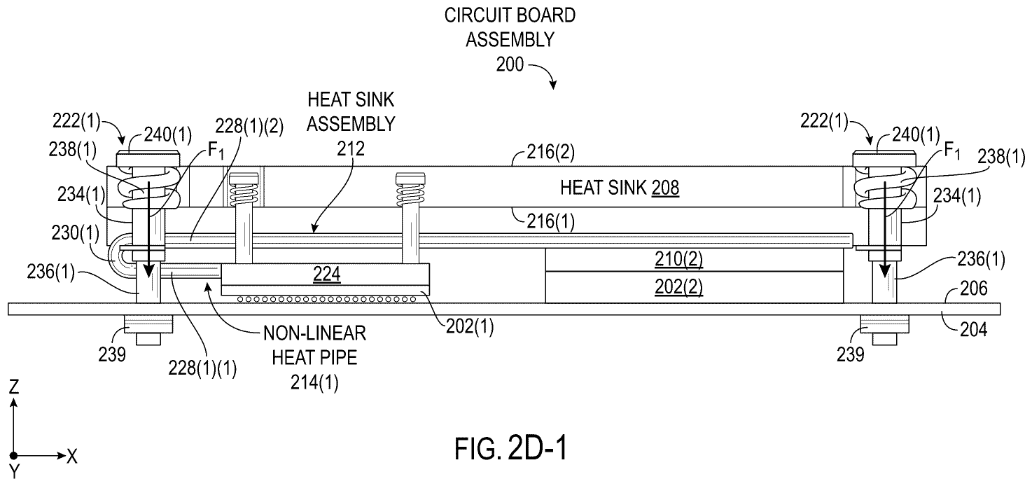

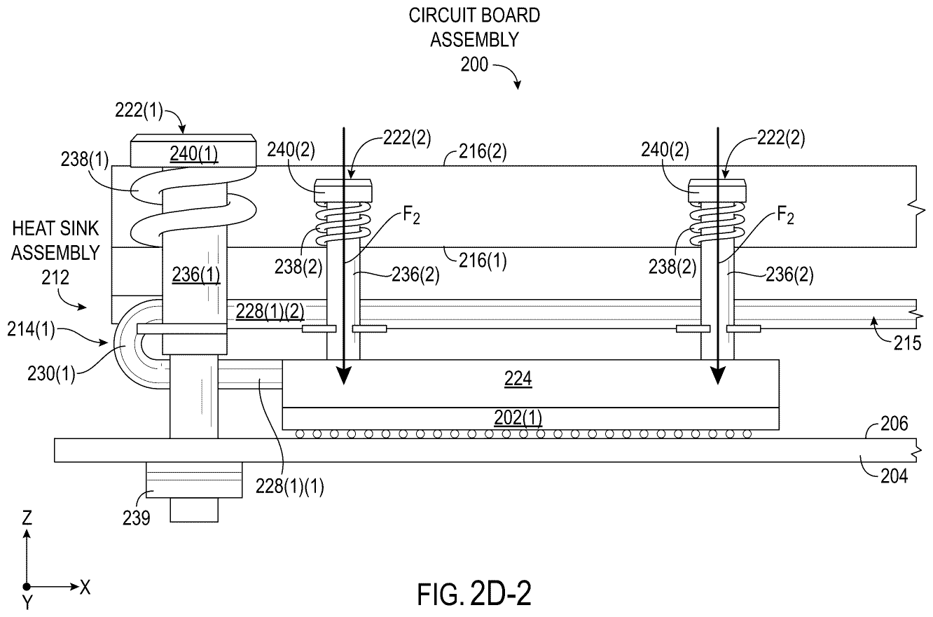

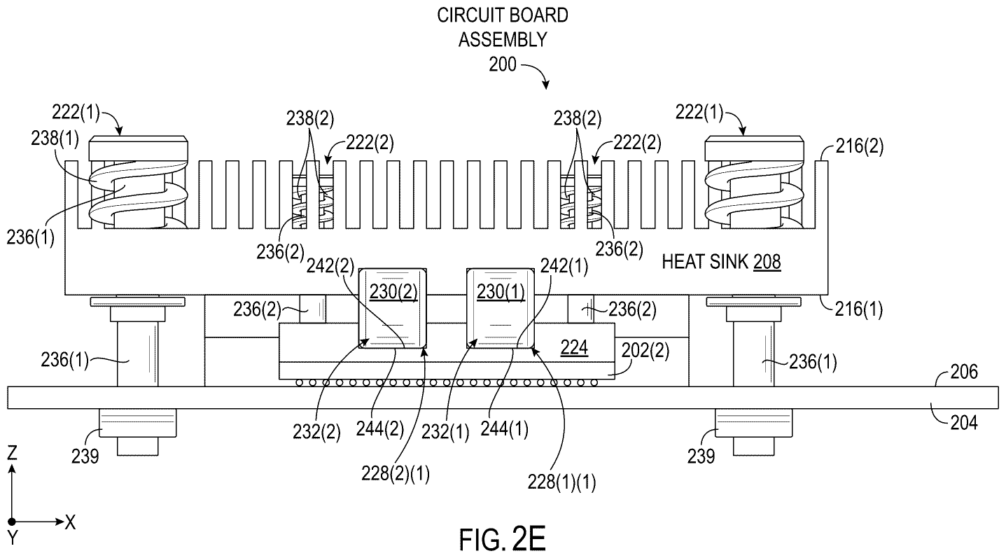

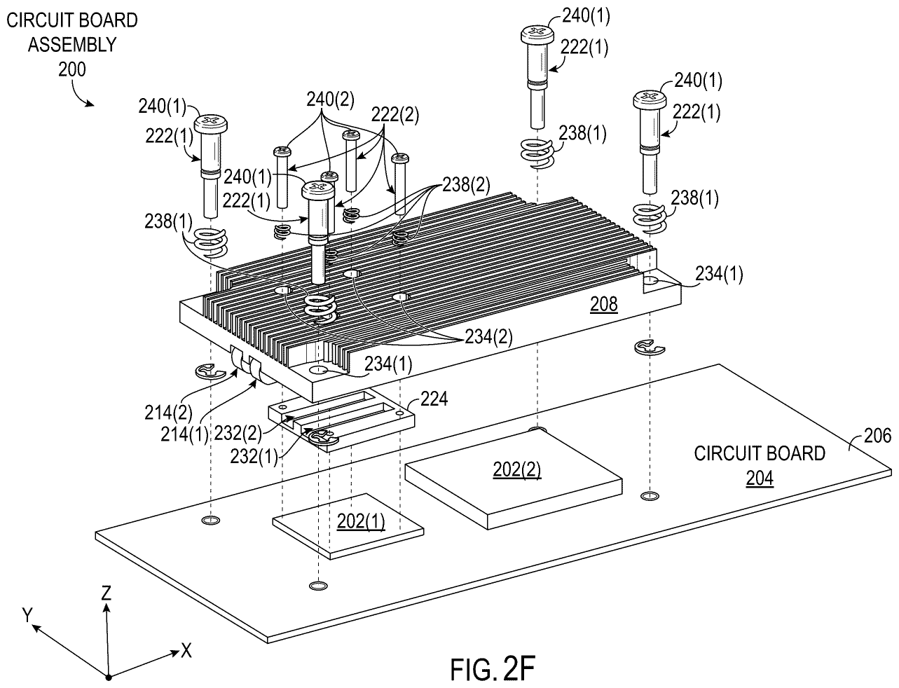

In this regard, FIG. 2A is a perspective side view of an exemplary circuit board assembly 200 that includes first and second electronic devices 202(1), 202(2) in the form of IC chips in this example. Similar to the circuit board assembly 100 in FIGS. 1A and 1B, the first and second electronic devices 202(1), 202(2) are both of different respective first and second heights H₃, H₄ from a top surface 206 of a circuit board 204 in which the first and second electronic devices 202(1), 202(2) are mounted. The first height H₃ of the first electronic device 202(1) is smaller than the second height H₄ of the second electronic device 202(2). As shown in hidden lines in FIG. 2A, a single body heat sink 208 is provided in the circuit board assembly 200 as part of a heat sink assembly 212. The heat sink 208 has a first, bottom side 216(1) and a second, top side 216(2) opposite the first, bottom side 216(1) in the second, vertical direction (Z-axis direction) orthogonal to the first, horizontal directions (X-axis and Y-axis directions). The second, bottom side 216(2) of the heat sink 208 is disposed above, adjacent to, and thermally coupled to the first and second electronic devices 202(1), 202(2) in the second, vertical direction (Z-axis direction) to dissipate heat generated by the first and second electronic devices 202(1), 202(2). FIG. 2B illustrates another side, perspective view of the circuit board assembly 200 in FIG. 2A wherein the heat sink 208 is shown extending in first, horizontal directions (X-axis and Y-axis directions).

As discussed in more detail below, the heat sink assembly 212 also includes a spring-adjustable, non-linear heat pipe 214 secured between and thermally coupled to the first electronic device 202(1) and the heat sink 208. By a heat-pipe being “non-linear,” it is meant that the heat pipe does not extend in a straight line or plane in a given direction, but is bent or deformed from one component or different components in some manner to extend in different lines or planes so as to form a spring (e.g., a cantilevered spring) that can store energy as a result of force applied to the heat pipe. In this example, as discussed in more detail below, the heat pipe 214 is bent upon itself to form separate elongated sections extending in a different line(s)/plane(s) so as to form a non-linear spring 220 (“spring 220”) (e.g., a cantilevered spring) that can store energy as a result of force applied to the heat pipe 214. Thus, the spring 220 of the non-linear heat pipe can be loaded by the application of a downward force applied by a first, bottom side 216(1) of the heat sink 208 in the second, vertical direction (Z-axis) towards the circuit board 204 and onto the non-linear heat pipe 214. In this example, the spring 220 of the non-linear heat pipe 214 is formed an area intersecting the first electronic device 202(1) in the second, vertical direction (Z-axis direction) and coupled to the first electronic device 202(1) so that that application of force on the non-linear heat pipe 214 is directed to the first electronic device 202(1) to provide a tight thermal coupling for enhanced heat dissipation.

Also in this example, the non-linear heat pipe 214 is also part of or coupled to a linear heat pipe 215 that extends in the first, horizontal direction (X-axis direction) towards the second electronic device 202(1) to be disposed between and to couple the second electronic device 202(1) to the first, bottom side 216(1) of the heat sink 208 in the second, vertical direction (Z-axis direction). In this example, the non-linear heat pipe 214 and the linear heat pipe 215 are metal conduit(s) that contains liquid inside to provide a heat pipe functionality.

As will be discussed in more detail below, the heat sink 208 is configured to support first and second fasteners 222(1), 222(2) that not only couple the heat sink 208 to the circuit board 204 as part of the circuit board assembly 200, but are configured to cause the heat sink 208 to be compressed towards the circuit board 204 to cause the heat sink 208 to apply a downward force onto the non-linear heat pipe 214. In this example, a thermally conducive pedestal 224 (e.g., a metal block) is disposed in contact with the first electronic device 202(1) and is coupled to and supports the spring 220 formed in the non-linear heat pipe 214 to provide a thermal coupling between the first electronic device 202(1) and the non-linear heat pipe 214. An optional thermal paste could be disposed between the pedestal 224 and the first electronic device 202(1) to further enhance thermal conductivity between the pedestal 224 and the first electronic device 202(1). The non-linear heat pipe 214 is disposed between the first, bottom side 216(1) of the heat sink 208 and the pedestal 224 in the second, vertical direction (Z-axis direction). In this manner, the spring 220 formed in the non-linear heat pipe 214 is configured to, when under such load, provide an upward resilient force in the second, vertical direction (Z-axis direction) towards the heat sink 208 to provide a compressed, tight coupling between the heat sink 208 and the non-linear heat pipe 214.

Providing a tight coupling between the heat sink 208 and the non-linear heat pipe 214 provides a good thermal coupling between the heat sink 208 and the first electronic device 202(1). This may be particularly advantageous since the first electronic device 202(1) is of a smaller, first height H3 than the second height H4 of the second electronic device 202(2). Thus, with the single body heat sink 208 provided in the heat sink assembly 212 to dissipate heat, there will be a greater gap space between the first electronic device 202(1) and the heat sink 208 than between the second electronic device 202(1) and the heat sink 208. Thermal paste could be disposed between the first electronic device 202(1) and the heat sink 208 to fill in this gap space with a thermally conductive material coupled to the heat sink 208 and the first electronic device 202(1). However, a thermal paste may not be as efficient at heat transfer as a direct connection of metal material between the heat sink 208 and the first electronic device 202(1). A fixed height metal material, such as a metal block, could be provided to fill in the gap space between the first electronic device 202(1) and the heat sink 208. However, this would mean that the manufacturing tolerances of the metal block may need to be very precise so that when the single body heat sink 208 sits atop the first and second electronic devices 202(1), 202(2) in the second, vertical direction (Z-axis direction), the top surfaces of the metal block and the second electronic device 202(2) would be at or very close to the same height of the single body heat sink 208. This would be required for the heat sink 208 to make good contact with both the metal block and the second electronic device 202(2) equally for good thermal contact and thermal performance and without substantial “roll” in the second, vertical direction (Z-axis direction) that could degrade thermal transfer.

FIG. 2C is a close-up perspective side view of the circuit board assembly 200 in FIG. 2A to discuss more exemplary detail of the non-linear heat pipe 214 with its formed spring 220 supported by the pedestal 224 as part of the heat sink assembly 212. As shown in FIG. 2C, the pedestal 224 actually supports two (2), first and second non-linear heat pipes 214(1), 214(2) in this example. The first and second non-linear heat pipes 214(1), 214(2) and their respective formed springs 218(1), 218(2) are both located between the first, bottom side 216(1) of the heat sink 208 and the pedestal 224 in the second, horizontal direction (Z-axis direction). In this example, the first and second non-linear heat pipes 214(1), 214(2) extend in the first horizontal direction (X-axis direction) parallel to each other. In this example, both of the first and second non-linear heat pipes 214(1), 214(2) are formed from respective first and second elongated metal conduits 226(1), 226(2) that have internal chambers (not shown) that hold liquid to perform as a heat pipe. By “elongated metal conduits” it is meant that metal conduits extend a desired length in a given direction.

With continuing reference to FIG. 2C, the first and second elongated metal conduits 226(1), 226(2) are bent in the second, vertical direction (X-axis) back upon themselves to form separate first, bottom and top elongated metal sections 228(1)(1), 228(1)(2) for the first elongated metal conduit 226(1) and separate second, bottom and top elongated metal sections 228(2)(1), 228(2)(2) for the second elongated metal conduit 226(2), each extending in the first, horizontal direction (X-axis direction). The first, bottom and top elongated metal sections 228(1)(1), 228(1)(2) extend in the first, horizontal direction (X-axis direction) parallel to each other in the second, vertical direction (Z-axis direction). The second, bottom and top elongated metal sections 228(2)(1), 228(2)(2) also extend in the first, horizontal direction (X-axis direction) parallel to each other in the second, vertical direction (Z-axis direction), and parallel with the respective first, bottom and top elongated metal sections 228(1)(1), 228(1)(2) in the first, horizontal direction (X-axis direction). This forms cantilevered springs 218(1), 218(2) from both first and second elongated metal conduits 226(1), 226(2) that are each configured to be spring loaded to store energy when compressed in the second, vertical direction (Z-axis direction) by the heat sink 208. The bending of the first and second elongated metal conduits 226(1), 226(2) forms respective first and second bend radius sections 230(1), 230(2) between the respective first, bottom and top elongated metal sections 228(1)(1), 228(1)(2) and second, bottom and top elongated metal sections 228(2)(1), 228(2)(2), causing each non-linear heat pipe 214(1), 214(2) to be a C-shaped heat pipe when viewed from the side in the first, horizontal direction (Y-axis direction).

Also, with reference to FIG. 2C and as discussed in more detail below, the pedestal 224 contains respective first and second slots 232(1), 232(2) extending in the first, horizontal direction (X-axis direction). The first and second slots 232(1), 232(2) are sized in width in the first, horizontal direction (Y-axis direction) to receive the respective bottom elongated metal sections 228(1)(1), 228(2)(1) to support the respective non-linear heat pipes 214(1), 214(2) in physical and thermal contact with the pedestal 224.

FIGS. 2D-1 and 2D-2 are respective front side and close-up front side views of the circuit board assembly 200 in FIG. 2A to illustrate the non-linear heat pipes 214(1), 214(2) in contact with and compressed by the heat sink 208 to be placed under a load to provide a tight coupling between the heat sink 208 and the non-linear heat pipes 214(1), 214(2). In FIGS. 2D-1 and 2D-2, only the first non-linear heat pipe 214(1) is shown from the side view, but note the second non-linear heat pipe 214(2) is also present and behind the first non-linear heat pipe 214(1) in the first, horizontal direction (Y-axis direction) from the perspective of the view in FIGS. 2D-1 and 2D-2.

As shown in FIG. 2D-1, the heat sink 208 includes first holes 234(1) that are countersunk into the heat sink 208 from the second, top side 216(2) of the heat sink 208. There are actually four (4) first holes 234(1) configured to receive four (4) first fasteners 222(1) as shown in FIG. 2B, but only two(2) of the first holes 234(1) are shown in the view in FIG. 2D-1. The first holes 234(1) are configured to receive respective first fasteners 222(1) (e.g., screws) that are configured to extend through the first holes 234(1) and extend down to the circuit board 204. The first fasteners 222(1) have first shafts 236(1) that may be threaded and are configured to be tightened against a corresponding nut 239 to secure the heat sink 208 to the circuit board 204 as part of the circuit board assembly 200 and to also compress the heat sink 208 towards the circuit board 204 in the second, vertical direction (Z-axis direction). Compressing the heat sink 208 also compresses the coupling of the heat sink 208 to the non-linear heat pipes 214(1), 214(2) to provide an enhanced thermal coupling to the first and second electronic devices 202(1), 202(2). In this example, note that there is a thermal paste 210(2) disposed between the non-linear heat pipes 214(1), 214(2) and the second electronic device 202(2), but such is not required. Also, it is not required that the non-linear heat pipes 214(1), 214(2) extend towards the second electronic device 202(1) to intersect such in the second, vertical direction (Z-axis direction) such that it is part of the thermal conductive path between the second electronic device 202(1) and the heat sink 208. Additional thermal paste 210(2) could be used to bridge the gap space between the second electronic device 202(2) and the heat sink 208.

With continuing reference to FIG. 2D-1, in this example, the first fasteners 222(1) are spring-loaded fasteners in that they have first springs 238(1) disposed around their first shafts 236(1) that are sized larger than the widths of the first holes 234(1). Thus, when the first fasteners 222(1) are tightened, respective first heads 240(1) of the first fasteners 222(1) compress the first springs 238(1) against the heat sink 208 so as to provide one way to control the amount of first downward force F1 applied by the heat sink 208 to the non-linear heat pipes 214(1), 214(2) in the second, vertical direction (Z-axis direction). In this manner, the tightening of the first fasteners 222(1) can be adjusted to control the amount of first downward force F1 applied by the heat sink 208 in the second, vertical direction (Z-axis direction). In this example, the first holes 234(1) extend through the heat sink 208 to the first, bottom side 216(1) and are outside of the footprint area of the pedestal 224 in the first, horizontal directions (X-axis and Y-axis directions). Thus, tightening the first fasteners 222(1) does affect the amount of first downward force F1 that the heat sink 208 applies to the first and second non-linear heat pipes 214(1), 214(2) through an angular force vector from the first downward force F1 since the first fasteners 222(1) are outside of the footprint of the pedestal 224 in the first, horizontal directions (X-axis and Y-axis directions) and do not intersect the pedestal 224 in the second, vertical direction (Z-axis direction). The first fasteners 222(1) are also provided to generally secure the heat sink 208 to the circuit board 204.

However, as shown in FIG. 2D-1 and in the close-up side view in FIG. 2D-2 of the circuit board assembly 200, in this example, the circuit board assembly 200 also includes second fasteners 222(2). The heat sink 208 includes second holes 234(2) that are also countersunk into the heat sink 208 from the second, top side 216(2) of the heat sink 208. There are actually four (4) second holes 234(2) configured to receive four (4) second fasteners 222(2) as shown in FIG. 2B, but only two(2) of the second holes 234(2) are shown in the view in FIG. 2D-1 and 2D-2. The second holes 234(2) are configured to receive respective second fasteners 222(2) (e.g., screws) that are configured to extend through the second holes 234(2) and extend down to the pedestal 224. The second fasteners 222(2) have respective second shafts 236(2) that may be threaded and are configured to be tightened against a corresponding nut 239 in the pedestal 224 to also secure the heat sink 208 to the pedestal 224 as part of the circuit board assembly 200. This also causes the heat sink 208 to apply a second force F2 directly towards the non-linear heat pipes 214(1), 214(2) in the second, vertical direction (Z-axis direction) to have a method to more precisely adjust and control the compression between the heat sink 208 and the first and second linear heat pipes 214(1), 214(2), to control the thermal coupling therebetween. For example, it may be desired to tighten the first fasteners 222(1) to generally secure the heat sink 208 towards the circuit board 204. However, the presence of the second fasteners 222(2) allows more precise control of the second force F2 directly applied by the heat sink 208 to the first and second non-linear heat pipes 214(1), 214(2) to more precisely control the amount of compression and second pressure between the heat sink 208 and the first and second non-linear heat pipes 214(1), 214(2). This can compensate for variations in tolerance between the heights of the first and second electronic devices 202(1), 202(2) while still achieving the desired thermal performance for heat dissipation through the heat sink 208.

With continuing reference to FIGS. 2D-1 and 2D-2, in this example, the second fasteners 222(2) are spring-loaded fasteners in that they have second springs 238(2) disposed around their second shafts 236(2) that are sized larger than the widths of the second holes 234(2). Thus, when the second fasteners 222(2) are tightened, respective second heads 240(2) of the second fasteners 222(2) compress the second springs 238(2) against the heat sink 208 so as to provide a way to control the amount of second downward force F₂ directly applied by the heat sink 208 to the non-linear heat pipes 214(1), 214(2) in the second, vertical direction (Z-axis direction). In this manner, the tightening of the second fasteners 222(2) can be adjusted to more precisely control the amount of second downward force F₂ applied by the heat sink 208 in the second, vertical direction (Z-axis direction). In this example, the second holes 234(2) extend through the heat sink 208 to the first, bottom side 216(1) such that the second shafts 236(2) of the second fasteners 222(2) extend within of the footprint area of the pedestal 224 in the first, horizontal directions (X-axis and Y-axis directions). In other words, the second shafts 236(2) of the second fasteners 222(2) intersect the pedestal 224 and are configured to be secured within the pedestal 224. Thus, tightening the second fasteners 222(2) does affect the amount of first downward force F₂ that the heat sink 208 applies to the first and second non-linear heat pipes 214(1), 214(2) through the straight vector, non-angled second downward force F₂ directly since the second fasteners 222(2) are inside of the footprint of the pedestal 224 in the first directions (X-axis and Y-axis directions) and intersect the pedestal 224 in the second, vertical direction (Z-axis direction).

In this manner, by providing the separate first and second fasteners 222(1), 222(2) to secure the heat sink 208 to the circuit board 204 and the pedestal 224 of the heat sink assembly 212, the first fasteners 222(1) can be fastened such that the heat sink 208 applies the first downward force Fi to the circuit board 204 to create a first pressure between the heat sink 208 and the first and second non-linear heat pipes 214(1), 214(2) The second fasteners 222(2) can be separately fastened such that the heat sink 208 applies the second downward force F2 to the first and second non-linear heat pipes 214(1), 214(2) to create a second pressure between the heat sink 208 and the first and second non-linear heat pipes 214(1), 214(2). The second pressure may be different from the first pressure, and can be adjusted as needed to provide a desired thermal coupling between the first and second non-linear heat pipes 214(1), 214(2) and the heat sink 208.

FIG. 2E is a close-up, left side view of the circuit board assembly 200 in FIG. 2A. As shown in FIG. 2E, the first and second slots 232(1), 232(2) in the pedestal 224 that receive the respective bottom elongated metal sections 228(1)(1), 228(2)(1) can be seen in more detail. The first electronic device 202(1) is coupled to a first side 242(1) of the pedestal 224. The respective bottom elongated metal sections 228(1)(1), 228(2)(1) are coupled to a second side 242(2) of the pedestal 224 opposite the first side 242(1) in the second, vertical direction (Z-axis direction). In this example, the second side 242(2) of the pedestal 224 is formed by bottom surfaces 244(1), 244(2) of the respective first and second slots 232(1), 232(2). Other elements of the circuit board assembly 200 shown in FIG. 2E have already been discussed above with regard to FIGS. 2A-2D-2 and are not re-described.

FIG. 2F is a side perspective exploded view of the circuit board assembly 200 of FIG. 2A to illustrate more detail of the components that have been previously described in their exploded view. As shown in FIG. 2F, the first and second slots 232(1), 232(2) in the pedestal 224 can be seen in more detail. Other elements of the circuit board assembly 200 shown in FIG. 2F have already been discussed above with regard to FIGS. 2A-2D-2 and are not re-described.

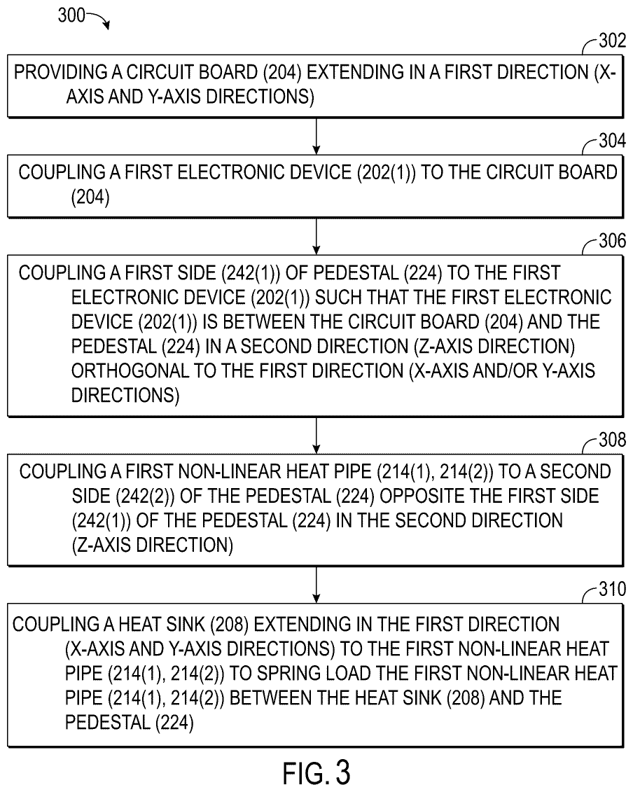

A circuit board assembly including a heat sink assembly that includes a spring-adjustable heat pipe secured between and thermally coupled to the first electronic device and a heat sink to provide an upward resilient force in a vertical direction towards the heat sink in response to the heat sink applying a downward force in a vertical direction onto the spring-adjustable heat pipe, to provide a compressed, tight coupling between the heat sink and the spring-adjustable heat pipe to provide a good thermal coupling between the heat sink and the first electronic device including, but not limited to, the circuit board assembly 200 in FIGS. 2A-2F with its heat sink assembly 212 can be assembled in an assembly process. In this regard, FIG. 3 is a flowchart illustrating an exemplary assembly process 300 of assembling a circuit board assembly including a heat sink assembly that includes a spring-adjustable heat pipe secured between and thermally coupled to the first electronic device and a heat sink to provide an upward resilient force in a vertical direction towards the heat sink in response to the heat sink applying a downward force in a vertical direction onto the spring-adjustable heat pipe, to provide a compressed, tight coupling between the heat sink and the spring-adjustable heat pipe to provide a good thermal coupling between the heat sink and the first electronic device including, but not limited to, the circuit board assembly 200 in FIGS. 2A-2F. The assembly process 300 in FIG. 3 is described with regard to the example circuit board assembly 200 in FIGS. 2A-2F, but such is not limited.

In this regard, as shown in FIG. 3, the assembly process 300 includes providing a circuit board 204 extending in first, horizontal directions (X-axis and Y-axis directions) (block 302 in FIG. 3). The assembly process 300 also includes coupling a first electronic device 202(1) to the circuit board 204 (block 304 in FIG. 3). The assembly process 300 also includes coupling a first side 242(1) of a pedestal 224 to the first electronic device 202(1) such that the first electronic device 202(1) is between the circuit board 204 and the pedestal 224 in a second, vertical direction (Z-axis direction) orthogonal to the first, horizontal directions (X-axis and/or Y-axis directions) (block 306 in FIG. 3). The assembly process 300 also includes coupling a first non-linear heat pipe 214(1) and/or 214(2) to a second side 242(2) of the pedestal 224 opposite the first side 242(1) of the pedestal 224 in the second, vertical direction (Z-axis direction) (block 308 in FIG. 3). The assembly process 300 also includes coupling a heat sink 208 extending in the first, horizontal directions (X-axis and Y-axis directions) to the first non-linear heat pipe 214(1) and/or 214(2) to spring load the first non-linear heat pipe 214(1) and/or 214(2) between the heat sink 208 and the pedestal 224 (block 310 in FIG. 3).

Other fabrication processes can also be employed for a circuit board assembly including a heat sink assembly that includes a spring-adjustable heat pipe secured between and thermally coupled to the first electronic device and a heat sink to provide an upward resilient force in a vertical direction towards the heat sink in response to the heat sink applying a downward force in a vertical direction onto the spring-adjustable heat pipe, to provide a compressed, tight coupling between the heat sink and the spring-adjustable heat pipe to provide a good thermal coupling between the heat sink and the first electronic device including, but not limited to, the circuit board assembly 200 in FIGS. 2A-2F with its heat sink assembly 212.

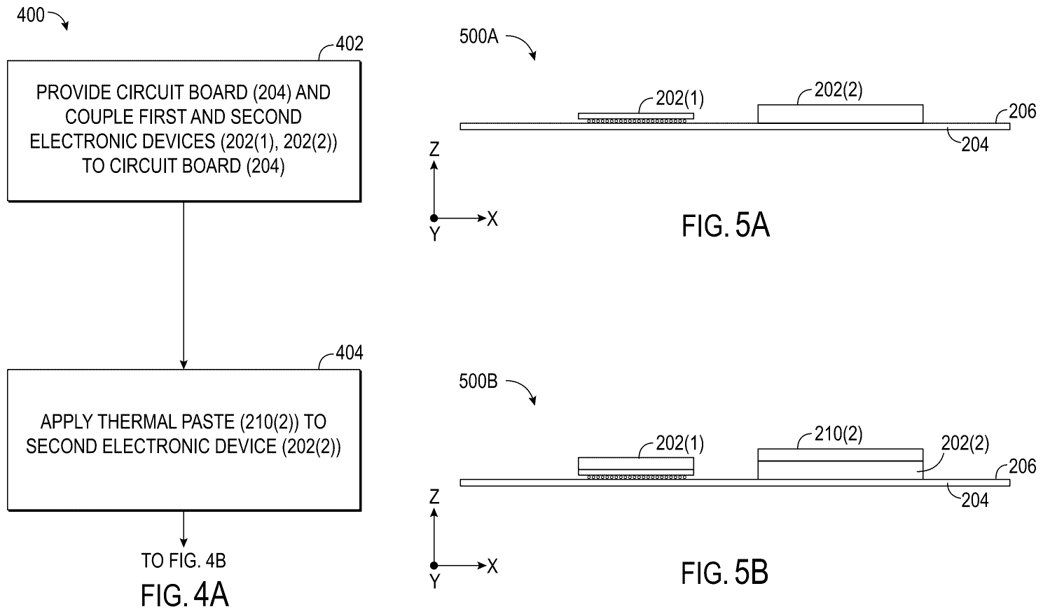

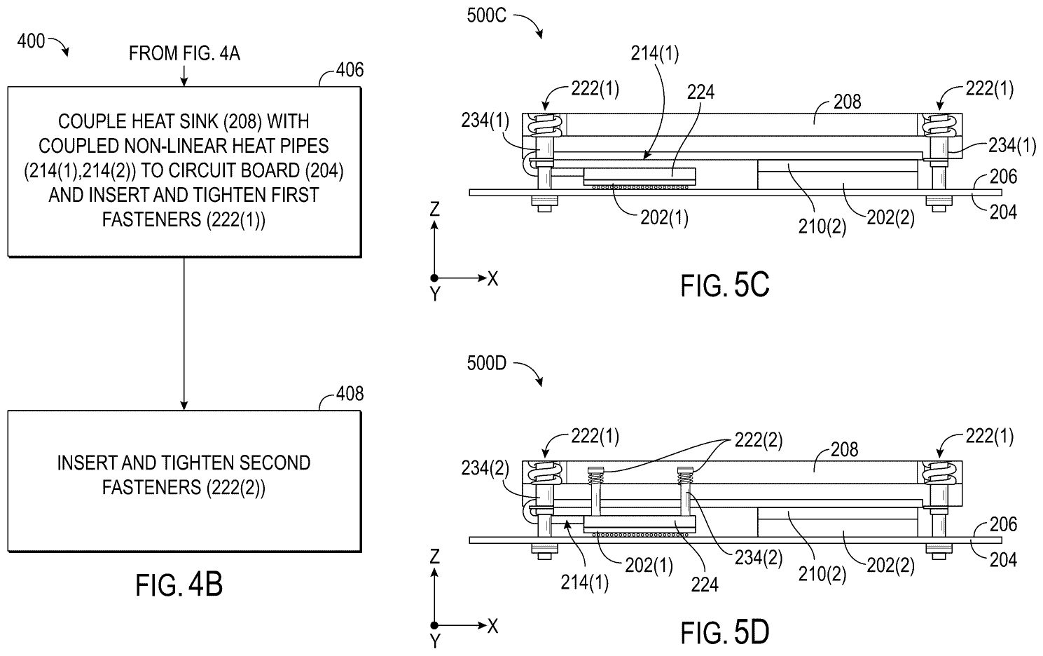

In this regard, FIGS. 4A and 4B is a flowchart illustrating another exemplary assembly process 400 of assembling the circuit board assembly 200 in FIG. 2A, including its heat sink assembly 212. FIGS. 5A-5D are exemplary fabrication stages 500A-500D of the assembly process 400 of assembling the circuit board assembly 200, including its heat sink assembly 212, as described in FIGS. 4A and 4B.

In this regard, as shown in the exemplary fabrication stage 500A in FIG. 5A, a first step of the assembly process 400 can be to provide the circuit board 204 and to mount or couple the first and second electronic devices 202(1), 202(2) to the circuit board 204 (block 402 in FIG. 4A). Then, as shown in the exemplary fabrication stage 500B in FIG. 5B, a next step of the assembly process 400 can be to apply an optional thermal paste 210(1) to the second electronic device 202(2) to fill in a gap space expected to be created between the second electronic device 202(2) and the first and second non-linear heat pipes 214(1), 214(2) to ensure a good thermal coupling between the second electronic device 202(2) and the first and second non-linear heat pipes 214(1), 214(2) (block 404 in FIG. 4A).

Then, as shown in the exemplary fabrication stage 500C in FIG. 5C, a next step of the assembly process 400 can be to couple the heat sink 208 with its coupled first and second non-linear heat pipes 214(1), 214(2) to the circuit board 204 (block 406 in FIG. 4B). In this example, the first and second non-linear heat pipes 214(1), 214(2) were previously coupled to the heat sink 208 (e.g., soldered or epoxy bonded), and thus are part of the heat sink 208 when coupled to the circuit board 204. As previously discussed, this involves inserting the first fasteners 222(1) in the first holes 234(1) in the heat sink 208 and tightening the first fasteners 222(1) against the nuts 239 to couple and compress the heat sink 208 against the first and second non-linear heat pipes 214(1), 214(2). Then, as shown in the exemplary fabrication stage 500D in FIG. 5D, a next step of the assembly process 400 involves inserting the second fasteners 222(2) in the second holes 234(2) in the heat sink 208 and tightening the second fasteners 222(2) against the nuts 239 to more precisely compress the heat sink 208 against the first and second non-linear heat pipes 214(1), 214(2) to provide the desired pressure between the heat sink 208 and the first and second non-linear heat pipes 214(1), 214(2) (block 408 in FIG. 4B).

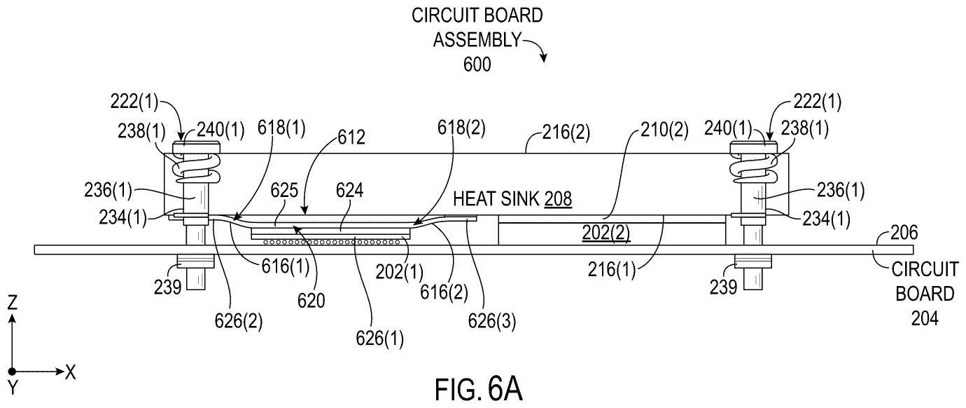

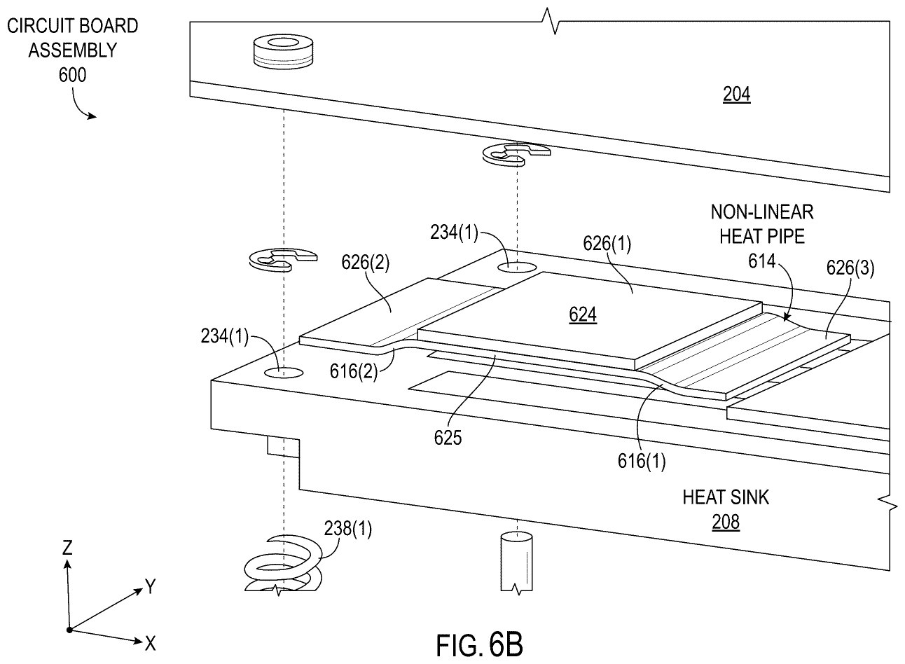

FIGS. 6A is a side view of an alternative circuit board assembly 600 that includes a non-linear heat pipe 614 that can be employed to provide good thermal coupling between the heat sink 208 and the first electronic device 202(1). Common elements between the circuit board assembly 600 in FIG. 6A and the circuit board assembly 200 in FIGS. 2A-2F are shown with common element numbers.

As shown in FIG. 6A, the circuit board assembly 600 includes an alternative spring-adjustable non-linear heat pipe 614 (“non-linear heat pipe 614”) that couples the heat sink 208 to a pedestal 624 (e.g., a metal pedestal) as part of a heat sink assembly 612 that is coupled to the first electronic device 202(1). The non-linear heat pipe 614 is in contact with and compressed by the heat sink 208 to be placed under a load to provide a tight coupling between the heat sink 208 and the non-linear heat pipe 614 to provide a good thermal coupling to the first electronic device 202(1). FIG. 6B is a close-up, bottom perspective exploded view of the circuit board assembly 600 in FIG. 6A.

The heat sink assembly 212 also includes the non-linear heat pipe 614 secured between and thermally coupled to the first electronic device 202(1) and the heat sink 208. By non-linear, it is meant that the heat pipe 614 does not extend in a straight line or plane in the first, horizontal direction (X-axis direction), but as shown in this example, the heat pipe 614 is bent in sections so as to form a cantilevered spring. In this example, the non-linear heat pipe 614 is a metal plate that has an internal chamber that contains liquid inside to provide a heat pipe functionality. The non-linear heat pipe 614 is an elongated metal conduit 625 heat pipe that includes two sections 616(1), 616(2) bent in a particular shape to form a non-linear spring 620 (“spring 620”) in an area of the non-linear heat pipe 214 intersecting the first electronic device 202(1) in the second, vertical direction (Z-axis direction) and coupled to the first electronic device 202(1). The spring 620 is loaded by the application of a downward force applied by a first, bottom side 216(1) of the heat sink 208 in the second, vertical direction (Z-axis) towards the circuit board 204 and onto the non-linear heat pipe 614.

In this example, the thermally conductive pedestal 624 (e.g., a metal block) is disposed in contact with the first electronic device 202(1) and is coupled to and supports the non-linear heat pipe 614 and provides a thermal coupling between the first electronic device 202(1) and the non-linear heat pipe 614. An optional thermal paste could be disposed between the pedestal 624 and the first electronic device 202(1) to further enhance thermal conductivity between the pedestal 624 and the first electronic device 202(1). The non-linear heat pipe 614 is disposed between the first, bottom side 216(1) of the heat sink 208 and the pedestal 624 in the second, vertical direction (Z-axis direction). In this manner, the spring 620 formed in the non-linear heat pipe 214 is configured to, when under such load, provide an upward resilient force in the second, vertical direction (Z-axis direction) towards the heat sink 208 to provide a compressed, tight coupling between the heat sink 208 and the non-linear heat pipe 614.

With continuing reference to FIG. 6A, the non-linear heat pipe 614 includes a first elongated metal section 626(1) as part of the elongated metal conduit 625 extending in the first, horizontal direction (X-axis and/or Y-axis direction(s)) and coupled to the pedestal 624. In this example, since the first elongated metal section 626(1) is a metal plate, the pedestal 624 can lay flat on the first elongated metal section 626(1) without the need to provide slots in the pedestal 624 like in the pedestal 224 in the circuit board assembly 200 in FIGS. 2A-2F. The non-linear heat pipe 614 also includes the bent sections 616(1), 616(2) that are bent at an angle to the first, horizontal direction (X-axis and/or Y-axis direction(s)) that are then coupled to second and third elongated metal sections 626(2), 626(3) as part of the elongated metal conduit 625 extending in the first, horizontal direction (X-axis and/or Y-axis direction(s)) and coupled to the heat sink 208. In this manner, the non-linear heat pipe 614 is a V-shaped heat pipe. This forms cantilevered springs 618(1), 618(2) formed from the elongated metal sections 626(1)-626(3) that are each configured to be spring loaded to store energy when compressed in the second, vertical direction (Z-axis direction) by the heat sink 208.

The first fasteners 222(1) are configured to be tightened against the corresponding nuts 239 to secure the heat sink 208 to the circuit board 204 as part of the circuit board assembly 200 and to also compress the heat sink 208 towards the circuit board 204 in the second, vertical direction (Z-axis direction). Compressing the heat sink 208 also compresses the coupling of the heat sink 208 to the non-linear heat pipe 614 to provide an enhanced thermal coupling to the first and second electronic devices 202(1), 202(2). In this example, note that there is a thermal paste 210(2) disposed between the heat sink 208 and the second electronic device 202(2), but such is not required. Also, in this example, the non-linear heat pipe 614 does not extend towards the second electronic device 202(2) to intersect such in the second, vertical direction (Z-axis direction) such that it is part of the thermal conductive path between the second electronic device 202(2) and the heat sink 208.

As discussed above with regard to the circuit board assembly 200 in FIGS. 2A-2F, the first fasteners 222(1) are spring-loaded fasteners in that they have first springs 238(1) disposed around their first shafts 236(1) that are sized larger than the widths of the first holes 234(1). Thus, when the first fasteners 222(1) are tightened, respective first heads 240(1) of the first fasteners 222(1) compress the first springs 238(1) against the heat sink 208 so as to provide one way to control the amount of first downward force applied by the heat sink 208 to the non-linear heat pipe 614 in the second, vertical direction (Z-axis direction). In this manner, the tightening of the first fasteners 222(1) can be controlled to control the amount of first downward force applied by the heat sink 208 in the second, vertical direction (Z-axis direction). In this example, the first holes 234(1) extend through the heat sink 208 to the first, bottom side 216(1) and are outside of the footprint area of the pedestal 224 in the first, horizontal directions (X-axis and Y-axis directions). Thus, tightening the first fasteners 222(1) does affect the amount of first downward force that the heat sink 208 applies to the non-linear heat pipe 614 through an angular force vector from the first downward force since the first fasteners 222(1) are outside of the footprint of the pedestal 224 in the first directions (X-axis and Y-axis directions) and do not intersect the pedestal 224 in the second, vertical direction (Z-axis direction). However, because the non-linear heat pipe 614 is provided as a metal plate that has a larger surface area than the non-linear heat pipes 214(1), 214(2) in the circuit board assembly 200, the first fasteners 222(1) can be used to precisely control the amount of force applied to the non-linear heat pipe 614.

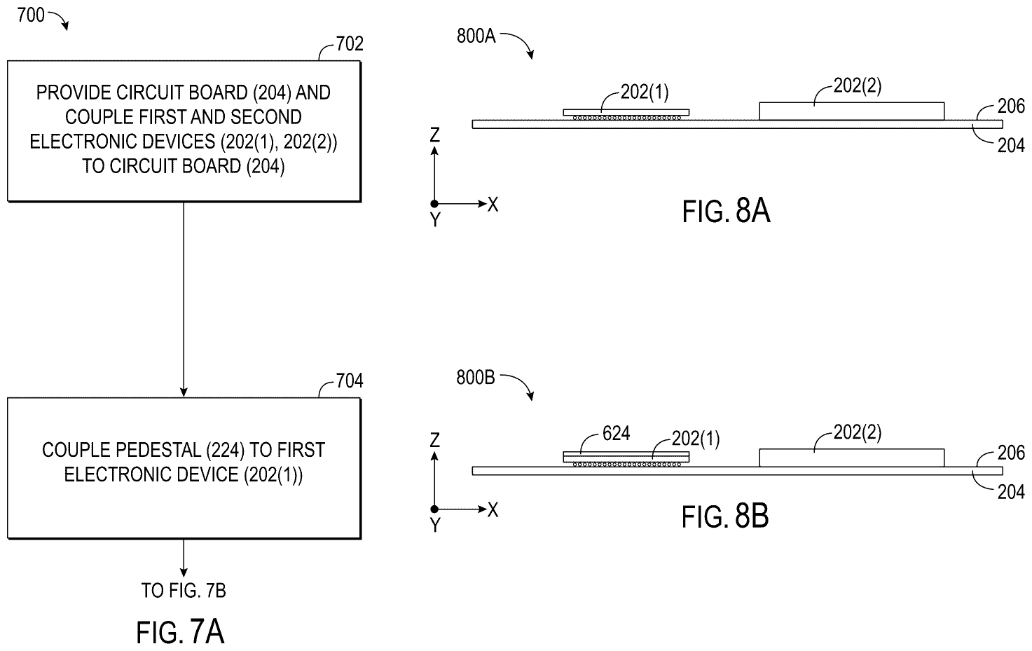

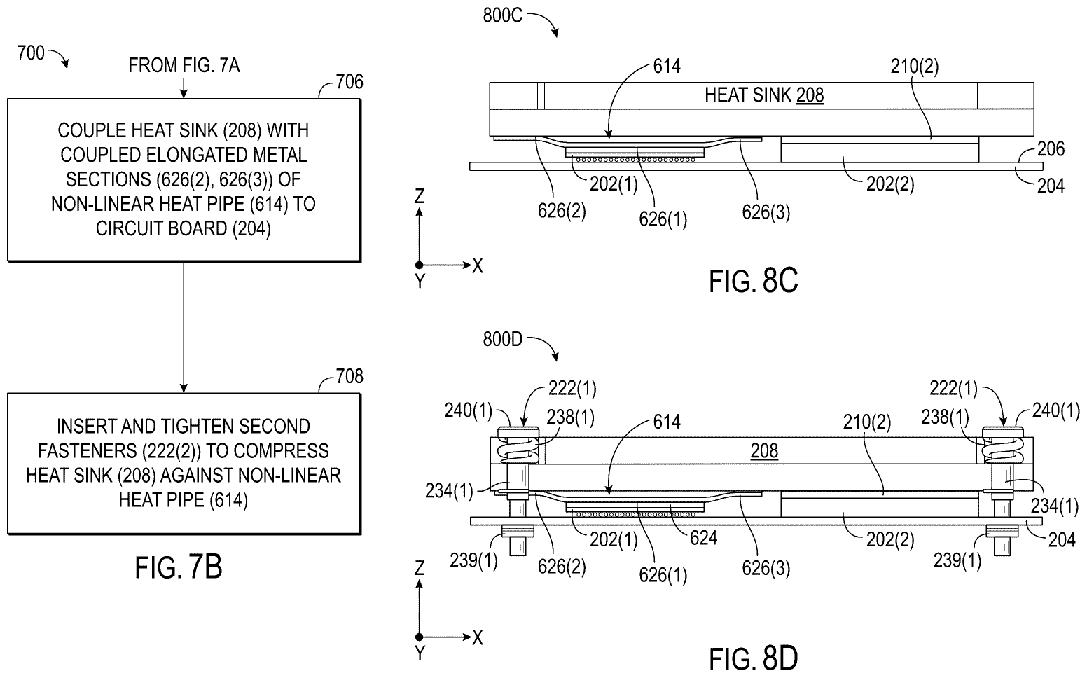

FIGS. 7A and 7B is a flowchart illustrating another exemplary assembly process 700 of assembling the circuit board assembly 600 in FIGS. 6A and 6B, including its heat sink assembly 612. FIGS. 8A-8D are exemplary fabrication stages 800A-800D of the assembly process 700 of assembling the circuit board assembly 600, including its heat sink assembly 612, as described in FIGS. 7A and 7B.

In this regard, as shown in the exemplary fabrication stage 800A in FIG. 8A, a first step of the assembly process 700 can be to provide the circuit board 204 and to mount or couple the first and second electronic devices 202(1), 202(2) to the circuit board 204 (block 702 in FIG. 7A). Then, as shown in the exemplary fabrication stage 800B in FIG. 8B, a next step of the assembly process 700 can be to couple the pedestal 624 to the first electronic device 202(1) (block 704 in FIG. 7A).

Then, as shown in the exemplary fabrication stage 800C in FIG. 8C, a next step of the assembly process 700 can be to couple the heat sink 208 and its non-linear heat pipe 614 to the circuit board 204. In this example, the non-linear heat pipe 614 is part of the heat sink 208 and is coupled to the heat sink 208 (e.g., through soldered connection, riveted, screwed, epoxy bonded) before being assembled to the circuit board 204. More specifically, the second and third elongated metal sections 626(2), 626(3) are coupled to the heat sink 208, and the non-linear heat pipe 614 is coupled to the circuit board 204 (block 706 in FIG. 7B). Then, as shown in the exemplary fabrication stage 800D in FIG. 8D, a next step of the assembly process 700 can be to insert the first fasteners 222(1) in the first holes 234(1) in the heat sink 208 and tighten the first fasteners 222(1) against the nuts 239 to couple and compress the heat sink 208 against the non-linear heat pipe 614 (block 708 in FIG. 7B).

Note that the terms “upper” and “top” where used herein are relative terms and are not meant to limit or imply a strict orientation that a “top” referenced element must always be oriented to be above a “bottom” referenced element, and vice versa. Note that the terms “lower” and “bottom” where used herein are relative terms and are not meant to limit or imply a strict orientation that a “bottom” or “lower” referenced element must always be oriented to be below a “top” or “upper” referenced element, and vice versa. Also, note that the terms “above” and “below” where used herein are relative terms and are not meant to limit or imply a strict orientation that an element referenced as being “above” another referenced element must always be oriented to be above the other referenced element with respect to ground, or that an element referenced as being “below” another referenced element must always be oriented to be below the other referenced element with respect to ground.

An object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

A circuit board assembly including a heat sink assembly that includes a spring-adjustable heat pipe secured between and thermally coupled to the first electronic device and a heat sink to provide an upward resilient force in a vertical direction towards the heat sink in response to the heat sink applying a downward force in a vertical direction onto the spring-adjustable heat pipe, to provide a compressed, tight coupling between the heat sink and the spring-adjustable heat pipe to provide a good thermal coupling between the heat sink and the first electronic device including, but not limited to, the circuit board assemblies 200, 600 with their heat sink assemblies 212, 612 in FIGS. 2A-2F, 5D, 6A-6B, and 8D, and that can be assembled in an assembly process including, but not limited to, the assembly processes 300, 400, 700 in FIGS. 3, 4A-4B, and 7A-7B, and according to aspects disclosed herein may be provided in or integrated into any processor-based device or wireless device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, and avionics systems.

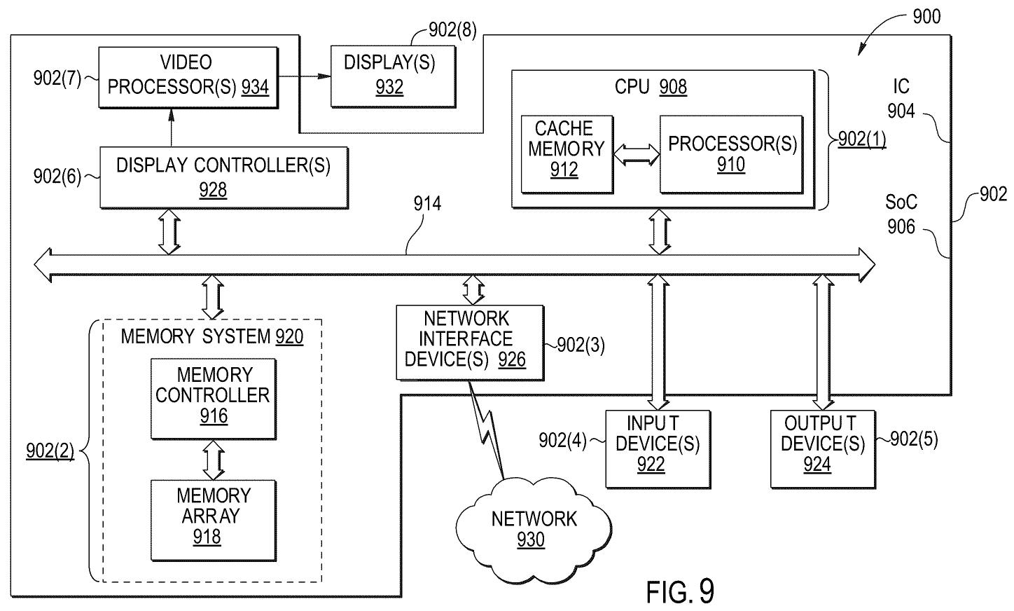

In this regard, FIG. 9 illustrates an example of a processor-based system 900 that can be included in one or more circuit board assemblies 902, 902(1)-902(8) that include a heat sink assembly that includes a spring-adjustable heat pipe secured between and thermally coupled to the first electronic device and a heat sink to provide an upward resilient force in a vertical direction towards the heat sink in response to the heat sink applying a downward force in a vertical direction onto the spring-adjustable heat pipe, to provide a compressed, tight coupling between the heat sink and the spring-adjustable heat pipe to provide a good thermal coupling between the heat sink and the first electronic device including, but not limited to, the circuit board assemblies 200, 600 with their heat sink assemblies 212, 612 in FIGS. 2A-2F, 5D, 6A-6B, and 8D, and that can be assembled in an assembly process including, but not limited to, the assembly processes 300, 400, 700 in FIGS. 3, 4A-4B, and 7A-7B, and according to any aspects disclosed.

In this example, the processor-based system 900 may be formed as an IC 904 in an IC package 903 and as a system-on-a-chip (SoC) 906. In this example, the processor-based system 900 may be provided as or include a system-on-a-chip (SoC) 906. The processor-based system 900 includes a CPU 908 that includes one or more processors 910, which may also be referred to as CPU cores or processor cores. The CPU 908 can be included in a circuit board assembly 902(1) to dissipate heat. The CPU 908 may have cache memory 912 coupled to the CPU 908 for rapid access to temporarily stored data. The CPU 908 is coupled to a system bus 914 and can intercouple master and slave devices included in the processor-based system 900. As is well known, the CPU 908 communicates with these other devices by exchanging address, control, and data information over the system bus 914. For example, the CPU 908 can communicate bus transaction requests to a memory controller 916 as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. The memory system 920 can be included in a circuit board assembly 902(2) to dissipate heat. The network interface devices 926 can be included in a circuit board assembly 902(3) to dissipate heat. Each of the memory system 920, the one or more input devices 922, the one or more output devices 924, the one or more network interface devices 926, and the one or more display controllers 928 can be provided in the same or different circuit packages. The input devices 922 and/or the output devices 924 can be included in a circuit board assembly 902(4), 902(5) to dissipate heat. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display controller(s) 928 sends information to the display(s) 932 to be displayed via one or more video processors 934, which process the information to be displayed into a format suitable for the display(s) 932. The display controller(s) 928 and video processor(s) 934 can be included in a circuit board assembly 902(6), 902(7) to dissipate heat and be provided in the same or different circuit packages, and in the same or different circuit packages containing the CPU 908 as an example. The display(s) 932 can include any type of display, including, but not limited to, a cathode ray tube (CRT), a liquid crystal display (LCD), a plasma display, a light emitting diode (LED) display, etc. The display(s) 932 can be included in a circuit board assembly 902(8) to dissipate heat.

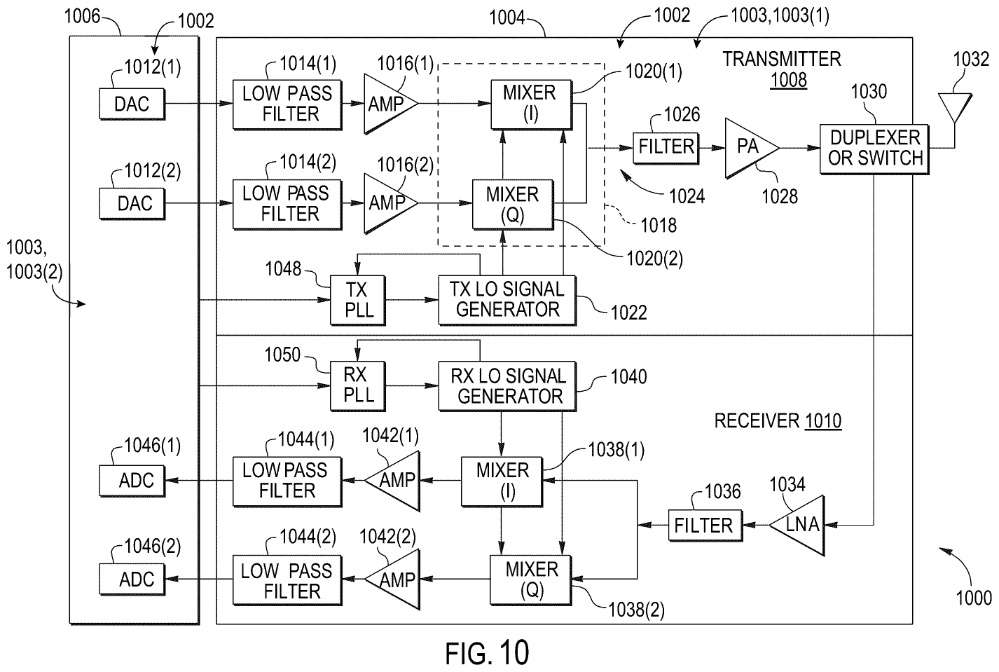

FIG. 10 illustrates an exemplary wireless communications device 1000 that includes radio frequency (RF) components formed from one or more ICs 1002. The wireless communications device 1000 that can be included in one or more circuit board assemblies 1003, 1003(1), 1003(2) that include a heat sink assembly that includes a spring-adjustable heat pipe secured between and thermally coupled to the first electronic device and a heat sink to provide an upward resilient force in a vertical direction towards the heat sink in response to the heat sink applying a downward force in a vertical direction onto the spring-adjustable heat pipe, to provide a compressed, tight coupling between the heat sink and the spring-adjustable heat pipe to provide a good thermal coupling between the heat sink and the first electronic device including, but not limited to, the circuit board assemblies 200, 600 with their heat sink assemblies 212, 612 in FIGS. 2A-2F, 5D, 6A-6B, and 8D, and that can be assembled in an assembly process including, but not limited to, the assembly processes 300, 400, 700 in FIGS. 3, 4A-4B, and 7A-7B, and according to any aspects disclosed. The wireless communications device 1000 may include or be provided in any of the above referenced devices, as examples. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage in receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into I and Q analog output signals, e.g., I and Q output currents, for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals from a TX LO signal generator 1022 through mixers 1020(1), 1020(2) to provide an upconverted signal 1024. A filter 1026 filters the upconverted signal 1024 to remove undesired signals caused by the frequency upconversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Downconversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency upconversion, while the RX LO signal generator 1040 generates the I and Q RX LO signals used for frequency downconversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. An electronic device, comprising:
a heat sink assembly, comprising:
   a heat sink extending in a first direction, the heat sink comprising a first side and a second side opposite the first side in a second direction orthogonal to the first direction;
   a pedestal configured to be coupled to a first electronic device; and
   a first non-linear heat pipe spring-loaded between the first side of the heat sink and the pedestal.
      2. The electronic device of clause 1, wherein the heat sink assembly further comprises a second non-linear heat pipe spring-loaded between the first side of the heat sink and the pedestal.
      3. The electronic device of clause 2, wherein the first non-linear heat pipe and the second non-linear heat pipe are parallel to each other in the first direction.
      4. The electronic device of any of clauses 1-3, wherein the first non-linear heat pipe comprises an elongated metal conduit bent back on itself in the second direction forming:
a first elongated metal section extending in the first direction and coupled to the pedestal; and
a second elongated metal section extending in the first direction and coupled to the second side of the heat sink.
   5. The electronic device of any of clauses 1-4, wherein the first non-linear heat pipe is C-shaped in the second direction.
   6. The electronic device of any of clauses 1-3, wherein the first non-linear heat pipe comprises an elongated metal conduit comprising:
a first elongated metal section extending in the first direction and coupled to the pedestal;
a first bent section bent at an angle to the first direction and coupled to a first end of the first elongated metal section;

a second bent section bent at an angle to the first direction and coupled to a second end of the first elongated metal section opposite the first end in the first direction;
a second elongated metal section extending in the first direction and coupled to the first bent section and coupled to the second side of the heat sink; and
a third elongated metal section extending in the first direction and coupled to the second bent section and coupled to the second side of the heat sink.
   7. The electronic device of any of clauses 1-6, wherein the first non-linear heat pipe is V-shaped in the second direction.
   8. The electronic device of clause 4, wherein the pedestal comprises a first slot extending in the first direction;
wherein the first elongated metal section is disposed in the first slot of the pedestal to couple the first elongated metal section to the pedestal.
   9. The electronic device of any of clauses 1-8, wherein the heat sink further comprises one or more second holes each extending from the first side of the heat sink to the second side of the heat sink and intersecting the pedestal in the second direction; and
further comprising:
   one or more second fasteners each extending through a second hole of the one or more second holes and secured to the pedestal.
      10. The electronic device of clause 9, wherein each of the one or more second fasteners comprises a second shaft and a second spring disposed around the second shaft, the second spring adjacent to the first side of the heat sink.
      11. The electronic device of any of clauses 1-10, further comprising:
a circuit board; and
the first electronic device mounted to the circuit board.
   12. The electronic device of clause 11, wherein the heat sink further comprises one or more first holes each extending from the first side of the heat sink to the second side of the heat sink and not intersecting the pedestal in the second direction; and
further comprising:
one or more first fasteners each extending through a first hole of the one or more first holes and secured to the circuit board.
   13. The electronic device of clause 12, wherein each of the one or more first fasteners comprises a first shaft and a first spring disposed around the first shaft, the first spring adjacent to the first side of the heat sink.
   14. The electronic device of clause 13, wherein the heat sink further comprises one or more second holes each extending from the first side of the heat sink to the second side of the heat sink and intersecting the pedestal in the second direction;
further comprising:
   one or more second fasteners each extending through a second hole of the one or more second holes and secured to the pedestal; and
each of the one or more second fasteners comprises a second shaft and a second spring disposed around the second shaft, the second spring adjacent to the first side of the heat sink.
   15. The electronic device of clause 14, wherein:
each of the one or more first fasteners are configured to be fastened to the circuit board to compress its first spring to cause the heat sink to apply a first downward force in the second direction towards the circuit board to create a first pressure between the heat sink and the first non-linear heat pipe in the second direction not intersecting the pedestal; and
each of the one or more second fasteners are configured to be fastened to the pedestal to compress its second spring to cause the heat sink to apply a second downward force to the first non-linear heat pipe in the second direction towards the pedestal to create a second pressure between the heat sink and the first non-linear heat pipe in the second direction intersecting the pedestal.
   16. The electronic device of any of clauses 11-15, further comprising a second electronic device mounted to the circuit board;
wherein:
   the first electronic device has a first height from the circuit board in the second direction;
   the second electronic device has a second height from the circuit board in the second direction greater than the first height; and
   the second side of the heat sink is thermally coupled to the second electronic device.
      17. The electronic device of clause 16, wherein the first non-linear heat pipe comprises:
a first elongated metal section extending in the first direction and coupled to the pedestal; and
a second elongated metal section extending in the first direction and coupled to the second side of the heat sink and thermally coupled to the first electronic device and the second electronic device.
   18. A method of assembling a heat sink assembly in an electronic device, comprising:
providing a circuit board extending in a first direction;
coupling a first electronic device to the circuit board;
coupling a first side of a pedestal to the first electronic device such that the first electronic device is between the circuit board and the pedestal in a second direction orthogonal to the first direction;
coupling a first non-linear heat pipe to a second side of the pedestal opposite the first side of the pedestal in the second direction; and
coupling a heat sink extending in the first direction to the first non-linear heat pipe to spring load the first non-linear heat pipe between the heat sink and the pedestal.
   19. The method of clause 18, wherein the first non-linear heat pipe comprises an elongated metal conduit bent back on itself in the second direction forming:
a first elongated metal section extending in the first direction and coupled to the pedestal; and
a second elongated metal section extending in the first direction and coupled to the second side of the heat sink;
wherein:
   coupling the first non-linear heat pipe to the second side of the pedestal further comprises coupling the second elongated metal section to the second side of the pedestal; and
   coupling the heat sink to the first non-linear heat pipe further comprises coupling the heat sink to the first elongated metal conduit.
      20. The method of clause 18, wherein the first non-linear heat pipe comprises an elongated metal conduit comprising:
a first elongated metal section extending in the first direction and coupled to the pedestal; and
a first bent section bent at an angle to the first direction and coupled to a first end of the first elongated metal section;
a second bent section bent at an angle to the first direction and coupled to a second end of the first elongated metal section opposite the first end in the first direction;
a second elongated metal section extending in the first direction and coupled to the first bent section and coupled to the second side of the heat sink; and
a third elongated metal section extending in the first direction and coupled to the second bent section and coupled to the second side of the heat sink;
wherein:
   coupling the first non-linear heat pipe to the second side of the pedestal further comprises coupling the first elongated metal section to the second side of the pedestal; and
   coupling the heat sink to the first non-linear heat pipe further comprises coupling the heat sink to the second elongated metal conduit and the third elongated metal section.

What is claimed is:

1. An electronic device, comprising:
a heat sink assembly, comprising:
a heat sink extending in a first direction, the heat sink comprising a first side and a second side opposite the first side in a second direction orthogonal to the first direction;
a pedestal configured to be coupled to a first electronic device; and
a first non-linear heat pipe spring-loaded between the first side of the heat sink and the pedestal.

2. The electronic device of claim 1, wherein the heat sink assembly further comprises a second non-linear heat pipe spring-loaded between the first side of the heat sink and the pedestal.

3. The electronic device of claim 2, wherein the first non-linear heat pipe and the second non-linear heat pipe are parallel to each other in the first direction.

4. The electronic device of claim 1, wherein the first non-linear heat pipe comprises an elongated metal conduit bent back on itself in the second direction forming:
a first elongated metal section extending in the first direction and coupled to the pedestal; and
a second elongated metal section extending in the first direction and coupled to the second side of the heat sink.

5. The electronic device of claim 1, wherein the first non-linear heat pipe is C-shaped in the second direction.

6. The electronic device of claim 1, wherein the first non-linear heat pipe comprises an elongated metal conduit comprising:
a first elongated metal section extending in the first direction and coupled to the pedestal;
a first bent section bent at an angle to the first direction and coupled to a first end of the first elongated metal section;
a second bent section bent at an angle to the first direction and coupled to a second end of the first elongated metal section opposite the first end in the first direction;
a second elongated metal section extending in the first direction and coupled to the first bent section and coupled to the second side of the heat sink; and
a third elongated metal section extending in the first direction and coupled to the second bent section and coupled to the second side of the heat sink.

7. The electronic device of claim 1, wherein the first non-linear heat pipe is V-shaped in the second direction.

8. The electronic device of claim 4, wherein the pedestal comprises a first slot extending in the first direction;
wherein the first elongated metal section is disposed in the first slot of the pedestal to couple the first elongated metal section to the pedestal.

9. The electronic device of claim 1, wherein the heat sink further comprises one or more second holes each extending from the first side of the heat sink to the second side of the heat sink and intersecting the pedestal in the second direction; and
further comprising:
one or more second fasteners each extending through a second hole of the one or more second holes and secured to the pedestal.

10. The electronic device of claim 9, wherein each of the one or more second fasteners comprises a second shaft and a second spring disposed around the second shaft, the second spring adjacent to the first side of the heat sink.

11. The electronic device of claim 1, further comprising:
a circuit board; and
the first electronic device mounted to the circuit board.

12. The electronic device of claim 11, wherein the heat sink further comprises one or more first holes each extending from the first side of the heat sink to the second side of the heat sink and not intersecting the pedestal in the second direction; and
further comprising:
one or more first fasteners each extending through a first hole of the one or more first holes and secured to the circuit board.

13. The electronic device of claim 12, wherein each of the one or more first fasteners comprises a first shaft and a first spring disposed around the first shaft, the first spring adjacent to the first side of the heat sink.

14. The electronic device of claim 13, wherein the heat sink further comprises one or more second holes each extending from the first side of the heat sink to the second side of the heat sink and intersecting the pedestal in the second direction;
further comprising:
one or more second fasteners each extending through a second hole of the one or more second holes and secured to the pedestal; and
each of the one or more second fasteners comprises a second shaft and a second spring disposed around the second shaft, the second spring adjacent to the first side of the heat sink.

15. The electronic device of claim 14, wherein:
each of the one or more first fasteners are configured to be fastened to the circuit board to compress its first spring to cause the heat sink to apply a first downward force in the second direction towards the circuit board to create a first pressure between the heat sink and the first non-linear heat pipe in the second direction not intersecting the pedestal; and
each of the one or more second fasteners are configured to be fastened to the pedestal to compress its second spring to cause the heat sink to apply a second downward force to the first non-linear heat pipe in the second direction towards the pedestal to create a second pressure between the heat sink and the first non-linear heat pipe in the second direction intersecting the pedestal.

16. The electronic device of claim 11, further comprising a second electronic device mounted to the circuit board;
wherein:
the first electronic device has a first height from the circuit board in the second direction;
the second electronic device has a second height from the circuit board in the second direction greater than the first height; and
the second side of the heat sink is thermally coupled to the second electronic device.

17. The electronic device of claim 16, wherein the first non-linear heat pipe comprises:
a first elongated metal section extending in the first direction and coupled to the pedestal; and
a second elongated metal section extending in the first direction and coupled to the second side of the heat sink and thermally coupled to the first electronic device and the second electronic device.

18. A method of assembling a heat sink assembly in an electronic device, comprising:
providing a circuit board extending in a first direction;
coupling a first electronic device to the circuit board;
coupling a first side of a pedestal to the first electronic device such that the first electronic device is between the circuit board and the pedestal in a second direction orthogonal to the first direction;
coupling a first non-linear heat pipe to a second side of the pedestal opposite the first side of the pedestal in the second direction; and
coupling a heat sink extending in the first direction to the first non-linear heat pipe to spring load the first non-linear heat pipe between the heat sink and the pedestal.

19. The method of claim 18, wherein the first non-linear heat pipe comprises an elongated metal conduit bent back on itself in the second direction forming:
a first elongated metal section extending in the first direction and coupled to the pedestal; and
a second elongated metal section extending in the first direction and coupled to the second side of the heat sink;
wherein:
coupling the first non-linear heat pipe to the second side of the pedestal further comprises coupling the second elongated metal section to the second side of the pedestal; and
coupling the heat sink to the first non-linear heat pipe further comprises coupling the heat sink to the first elongated metal conduit.

20. The method of claim 18, wherein the first non-linear heat pipe comprises an elongated metal conduit comprising:
a first elongated metal section extending in the first direction and coupled to the pedestal; and
a first bent section bent at an angle to the first direction and coupled to a first end of the first elongated metal section;
a second bent section bent at an angle to the first direction and coupled to a second end of the first elongated metal section opposite the first end in the first direction;
a second elongated metal section extending in the first direction and coupled to the first bent section and coupled to the second side of the heat sink; and
a third elongated metal section extending in the first direction and coupled to the second bent section and coupled to the second side of the heat sink;
wherein:
coupling the first non-linear heat pipe to the second side of the pedestal further comprises coupling the first elongated metal section to the second side of the pedestal; and
coupling the heat sink to the first non-linear heat pipe further comprises coupling the heat sink to the second elongated metal conduit and the third elongated metal section.
